(19) United States
(12) Patent Application Publication
(10) Pub. No.: US 2016/0041201 A1
(43) Pub. Date: Feb. 11, 2016

(54) DIE STRUCTURE, CONTACT TEST STRUCTURE, AND CONTACT TESTING METHOD UTILIZING THE CONTACT TEST STRUCTURE

(71) Applicant: MACRONIX International Co., Ltd., Hsinchu (TW)

(72) Inventors: Che-Lun Hung, Hsinchu (TW); Hsiao-Leng Li, Hsinchu (TW)

(21) Appl. No.: 14/456,827

(22) Filed: Aug. 11, 2014

(51) Int. Cl. G01R 1/07; G01R 31/28

(52) U.S. Cl. CPC G01R 1/07; G01R 31/28

(57) ABSTRACT

A die structure is described, including a device area and a contact test area. The device area has therein a device structure including a first contact plug. The contact test area has therein a contact test structure that includes a second contact plug and is different from the device structure. The contact test structure is also described, including a well, a heavily doped region in the well, and a contact plug, wherein the heavily doped region and the well are both of N-type or are both of P-type, and the contact plug is disposed over the heavily doped region.

### BACKGROUND OF THE INVENTION

1. Field of Invention

This invention relates to the electron beam (e-beam) inspection technology applied in IC processes, and particularly relates to a contact test structure suitable for e-beam inspection, a die structure including a contact test area having therein a contact test structure suitable for e-beam inspection, and a contact testing method utilizing the contact test structure.

2. Description of Related Art

Due to the inconsistent of the environment of contact plugs of a flash memory array, it is not easy to detect contact open in ordinary products using general inspection methods. Moreover, though increasing the sensitivity of a useful inspection tool to meet the requirement of a contact open detection beyond 50 nm node is easy, it is difficult to point out the defect of interesting (DOI) because the noise (nuisance) become worse than previous generation.

E-beam inspection is a solution for the above problems. In such method, typically, an electron beam is emitted to irradiate a contact test area on a wafer, the induced secondary electrons are detected through the contact plugs in the contact test area, and any contact plug transmitting no secondary electrons is determined to be bad or open. The detection modes are classified into retarding mode and extracting mode, which two are described below.

FIG. 1 illustrates a detection in the retarding (−Ve) mode. Each of the memory cells of which the contact plugs 14a/b are to be tested includes a N⁺-doped source/drain (S/D) region 10 in a P-well 12. Due to the forward bias of PN junction, the secondary electrons are readily released from the heavily doped region 10 into the P-well 12. For a good contact plug 14a, secondary electrons released into the P-well 12 can be readily detected through it. For a bad contact plug 14b, no secondary electron can be detected through it due to the open circuit. Thereby, the bad contact plugs can be determined. However, the retarding mode detection has a problem of residual defect noise.

FIG. 2 illustrates a detection in the extracting (+Ve) mode. For a good contact plug 14a, the secondary electrons are difficult to move from the heavily doped region 10 to it due to the reverse bias of PN junction, but a small amount of 2^{nd} electrons can still be detected so that the bad contact plug 14b, which transmits no 2^{nd} electrons, can be identified. However, the extracting mode detection has a problem of inconsistent brightness of good contacts due to current leakage.

FIG. 3 illustrates a detection in the extracting mode with an advanced charging control (ACC). For good contact plugs 14a/a′, the amount of the detected secondary electrons can be increased to facilitate the detection, but there is still the problem of inconsistent brightness of good contacts due to current leakage. That is, the signals of some good contact plugs 14a′ are brighter than those of the other good contact plugs 14a.

### SUMMARY OF THE INVENTION

In view of the foregoing, this invention provides a contact test structure more suitable for e-beam inspection.

This invention also provides a die structure including a contact test area having therein a contact test structure suitable for e-beam inspection.

This invention further provides a contact testing method utilizing the contact test structure of this invention.

The die structure of this invention includes a device area and a contact test area.

The device area has therein a device structure that includes a first contact plug. The contact test area has therein a contact test structure that includes a second contact plug and is different from the device structure.

In an embodiment, the contact test structure is different from the device structure in a doping structure in a semiconductor substrate under the contact plugs. In such case, it is possible that the device structure includes a first heavily doped region of a first conductivity type, a first well of a second conductivity type in which the first heavily doped region is located, and the first contact plug which is disposed over the first heavily doped region, and the contact test structure includes a second well, a second heavily doped region in the second well, and the second contact plug, wherein the second well and the second heavily doped region both have the first conductivity type or both have the second conductivity type, and the second contact plug is disposed over the second heavily doped region.

The contact test structure of this invention is as described above, including a well, a heavily doped region in the well, and a contact plug disposed over the heavily doped region, wherein the heavily doped region and the well are both of N-type or are both of P-type.

In an embodiment, the contact test structure does not include an isolation layer.

In an embodiment, the contact test structure further includes an isolation layer beside the heavily doped region, which is formed simultaneously with the isolation layer in the device structure in the device area.

The contact testing method of this invention comprises the steps below. A contact test structure as described above is formed on a substrate while a device structure as described above is formed on the same. The contact test structure is irradiated with an electron beam. The 2^{nd} electrons released into or extracted from the heavily doped region of the contact test structure are detected through the contact plug of the same. The contact plug is determined to be good or bad according to the amount of the detected 2^{nd} electrons. The detection mode may be the retarding mode or the extracting mode as described above.

In some embodiments of the above structures and method of this invention, the device structure comprises a memory cell structure, such as a flash memory cell structure, and the heavily doped region in the device structure comprises an S/D region.

Because the heavily doped region and the well of the contact test structure of this invention have the same conductivity type, any of the retarding mode and the extracting mode can be utilized for 2^{nd}-electron detection without the problems in the prior art due to the PN junction of the heavily doped region and the well. Although the contact test area cannot be utilized in the product chip, the little loss of device area is negligible from the viewpoint of the overall yield improvement.

In order to make the aforementioned and other objects, features and advantages of this invention comprehensible, a preferred embodiment accompanied with figures is described in detail below.

### BRIEF DESCRIPTION OF THE DRAWINGS

FIG. 1 illustrates a 2^{nd}-electron detection in the retarding (−Ve) mode in the prior art.

FIG. 2 illustrates a 2^{nd}-electron detection in the extracting (+Ve) mode in the prior art.

FIG. 3 illustrates a 2^{nd}-electron detection in the extracting mode with an advanced charging control (ACC) in the prior art.

FIG. 4 illustrates a die structure that includes a device area and a contact test area having therein a contact test structure according to a first embodiment of this invention.

FIG. 5 illustrates a die structure that includes a device area and a contact test area having therein a contact test structure according to a second embodiment of this invention.

FIG. 6 is a top view of a die structure including a contact test area much smaller than the device area according to an embodiment of this invention.

FIG. 7 illustrates a 2^{nd}-electron detection for a contact test structure of this invention in the retarding mode.

FIG. 8 illustrates a 2^{nd}-electron detection for a contact test structure of this invention in the extracting mode.

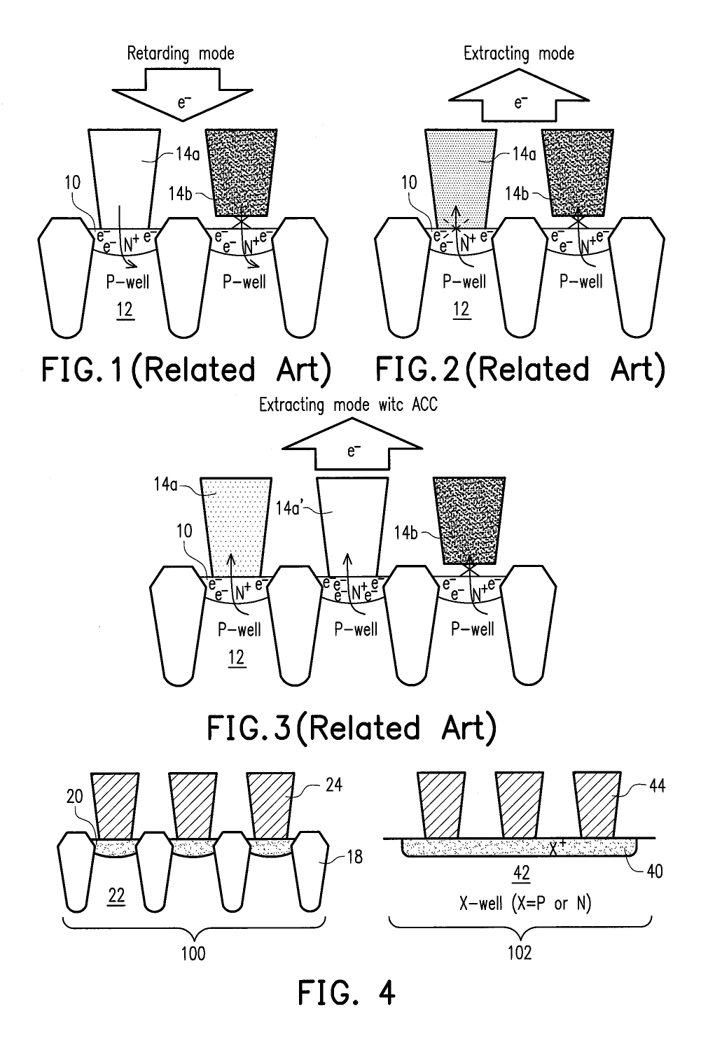

### DESCRIPTION OF EMBODIMENTS

This invention is further explained with the following embodiments, which are not intended to limit the scope thereof. For example, although the devices formed in the device area are memory cells in exemplary embodiments, the devices formed in the device area may alternatively be non-memory devices of which the contact plugs are to be tested.

FIG. 4 illustrates a die structure that includes a device area and a contact test area having therein a contact test structure according to the first embodiment of this invention.

Referring to FIG. 4, the die structure includes a device area 100 and a contact test area 102. The device area 100 has therein a device structure that includes an isolation layer 18 defining the active area, a heavily doped region 20 of a first conductivity type, a well 22 of a second conductivity type in which the heavily doped region 20 is located, and a contact plug 24 disposed over and intended to contact with the heavily doped region 20. The contact test area 102 has therein a contact test structure that includes a well 42, a heavily doped region 40 in the well 42, and a contact plug 44 disposed over and intended to contact with the heavily doped region 40, wherein the well 42 and the heavily doped region 40 both have the first conductivity type or both have the second conductivity type. The contact test structure does not include an isolation layer, because the contact test area 102 is masked in the process for forming the isolation layer 18 for the device area. The isolation layer 18 for the device area may be a shallow trench isolation (STI) layer.

When the devices in the device area 100 are memory cells, such as flash memory cells, the heavily doped region 20 of the device structure is an S/D region, and in most cases the heavily doped region 20 and the well 22 are N-type and P-type, respectively;

that is, the first conductivity type is N-type and the second one is P-type. Nevertheless, it is also possible that the first conductivity type is P-type and the second one is N-type, alternatively. No matter what the first or second conductivity type is, the heavily doped region 40 and the well 42 are both of the first conductivity type or are both of the second conductivity type. That is, the heavily doped region 40 and the well 42 are both of N-type or are both of P-type.

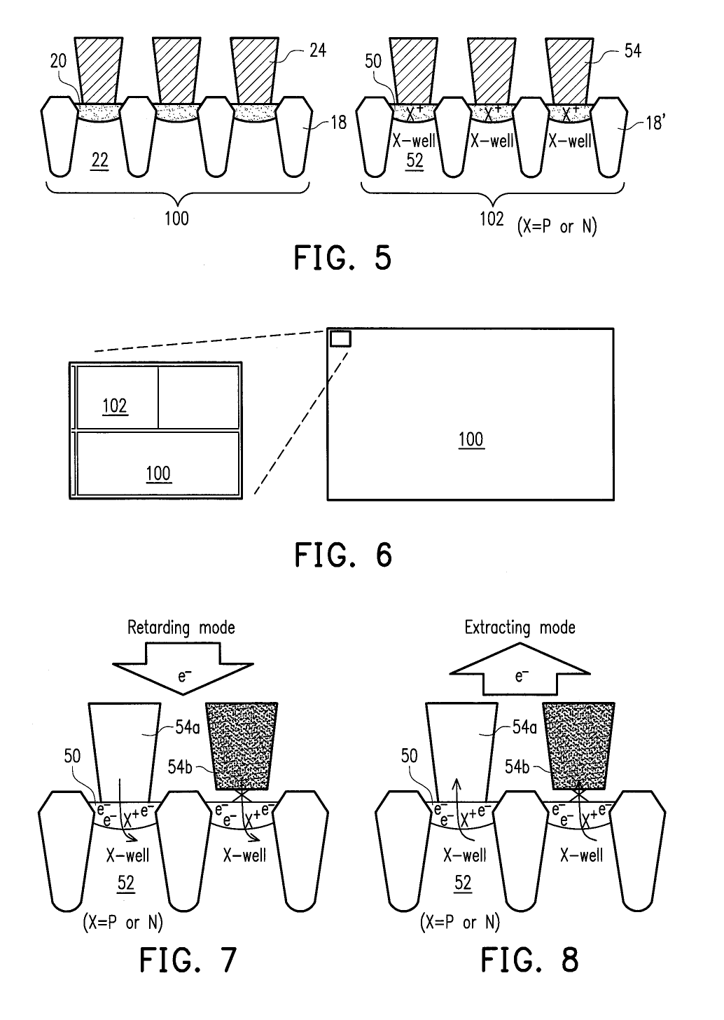

FIG. 5 illustrates a die structure that includes a device area and a contact test area having therein a contact test structure according to the second embodiment of this invention.

Referring to FIG. 5, the contact test structure in the second embodiment is different from that described in the first embodiment in that an isolation layer 18′, which is formed simultaneously with the isolation layer 18 in the device area 100, is disposed beside the heavily doped region 50 in the well 52 in the contact test area 102.

FIG. 6 is a top view of a die structure including a contact test area much smaller than the device area according to an embodiment of this invention.

Referring to FIG. 6, the die structure includes a device area 100 that occupies most of the total die area, and a contact test area 102 that takes a very small portion of the total die area and is much smaller than the device area 100. For example, when the full die is to be formed with 256 M bits of memory cells, the contact test area 102 may be one block in one sector in the die that otherwise is to be formed with 0.5 M bits of memory cells.

The contact test area 102 is not limited to be arranged at a corner of the die, and can be arranged in arbitrary location in the die. Moreover, if required, there may be a plurality of such contact test areas arranged in the die, and the contact test areas can be arranged in any required manner. The devise structure in the device area 100 and the contact test structure in the contact test area 102 may be the same as those described above and shown in FIGS. 4-5.

As for the 2^{nd}-electron detection in an e-beam inspection process utilizing the contact test structure of this invention, the detection may be conducted in any of the retarding mode and the extracting mode, which two are respectively illustrated as follows with the contact test structure having an isolation layer as shown in FIG. 5 as an example.

FIG. 7 illustrates a 2^{nd}-electron detection for the contact test structure in the retarding mode. Because the heavily doped region 50 and the well 52 of the contact test structure have the same conductivity type X, for a good contact plug 54a, second electrons can be readily released into the well 52 no matter what the conductivity type X is, and the signal is strong. For a bad contact plug 54b, no second electrons can be detected due to the open circuit.

FIG. 8 illustrates a 2^{nd}-electron detection for the contact test structure in the extracting mode. Because the heavily doped region 50 and the well 52 of the contact test structure have the same conductivity type X, for a good contact plug 54a, second electrons can be readily extracted from heavily doped region 50 no matter what the conductivity type X is, and the signal is bright. For a bad contact plug 54b, no second electrons can be detected due to the open circuit.

For the heavily doped region and the well of the contact test structure according to the above embodiments of this invention have the same conductivity type, any of the retarding mode and the extracting mode can be utilized for 2^{nd}-electron detection without the problems in the prior art due to the PN junction of the heavily doped region and the well. Though the contact test area cannot be utilized in the product chip, the little loss of device area is negligible from the viewpoint of the overall yield improvement.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A die structure, comprising:
a device area, having therein a device structure that includes a first contact plug; and
a contact test area, having therein a contact test structure that includes a second contact plug and is different from the device structure.

2. The die structure of claim 1, wherein the contact test structure is different from the device structure in a doping structure in a semiconductor substrate under the contact plugs.

3. The die structure of claim 2, wherein
the device structure comprises: a first heavily doped region of a first conductivity type, a first well of a second conductivity type in which the first heavily doped region is located, and the first contact plug, wherein the first contact plug is disposed over the first heavily doped region; and
the contact test structure comprises: a second well, a second heavily doped region in the second well, and the second contact plug, wherein the second well and the second heavily doped region both have the first conductivity type or both have the second conductivity type, and the second contact plug is disposed over the second heavily doped region.

4. The die structure of claim 3, wherein the device structure further comprises an isolation layer beside the first heavily doped region, but the contact test structure does not include an isolation layer.

5. The die structure of claim 3, wherein the device structure further comprises an isolation layer beside the first heavily doped region, and the contact test structure further comprises the isolation layer beside the second heavily doped region.

6. The die structure of claim 3, wherein the device structure comprises a memory cell structure, and the first heavily doped region comprises a source/drain region.

7. The die structure of claim 6, wherein the memory cell structure comprises a flash memory cell structure.

8. The die structure of claim 6, wherein the first conductivity type is N-type, and the second conductivity type is P-type.

9. A contact test structure, comprising:
a well;
a heavily doped region in the well, wherein the heavily doped region and the well are both of N-type or are both of P-type; and
a contact plug, disposed over the heavily doped region.

10. The contact test structure of claim 9, which does not include an isolation layer.

11. The contact test structure of claim 9, further comprising an isolation layer beside the heavily doped region.

12. A contact testing method, comprising:
forming a contact test structure as described in claim 3 while forming a device structure as described in claim 3;
irradiating the contact test structure with an electron beam;
detecting secondary electrons released into or extracted from the second heavily doped region through the second contact plug; and
determining the second contact plug to be good or bad according to an amount of the detected secondary electrons.

13. The contact testing method of claim 12, wherein the detection is in a retarding mode in which the released secondary electrons are detected.

14. The contact testing method of claim 12, wherein the detection is in an extracting mode in which the extracted secondary electrons are detected.

15. The contact testing method of claim 12, wherein the device structure comprises a memory cell structure, and the second heavily doped region comprises a source/drain region.

16. The contact testing method of claim 15, wherein the memory cell structure comprises a flash memory cell structure.
